(19) United States
(12) Patent Application Publication
(10) Pub. No.: US 2008/0105194 A1
(43) Pub. Date: May 8, 2008

(54) Gas supply system, gas supply method, method of cleaning thin film forming apparatus, thin film forming method and thin film forming apparatus

(76) Inventors: Ken Nakao, Nirasaki-Shi (JP); Hitoshi Kato, Oshu-Shi (JP); Tsuneyuki Okabe, Oshu-shi (JP); Mitsuhiro Okada, Nirasaki-Shi (JP); Manabu Honma, Oshu-Shi (JP); Tomoki Haneishi, Oshu-Shi (JP)

Correspondence Address: Michael A. Makuch;Smith, Gambrell & Russell, Suite 1130, 1130 Connecticut Avenue, N.W., Washington, DC, 20036, US

(21) Appl. No.: 11/907,409

(22) Filed: Oct. 11, 2007

(30) Foreign Application Priority Data
Oct. 12, 2006 (JP) 2006-278906

(51) Int. Cl. C23C 22/00; C23C 16/455; B08B 9/027

(52) U.S. Cl. 117/97; 118/715; 134/22.11; 118/695; 134/95.1; 134/22.12

(57) ABSTRACT

A thin film forming apparatus 1 comprises a reaction chamber 2, and an exhaust pipe 5 connected with the reaction chamber 2. A fluorine introducing pipe 17c and a hydrogen introducing pipe 17d are connected with the reaction chamber 2, in order to supply a cleaning gas containing fluorine gas and hydrogen gas into the reaction chamber 2 or into the exhaust pipe 5. The hydrogen introducing pipe 17d includes an inner fluid passage 174 and an outer fluid passage 175 formed to cover around the inner fluid passage 174. The hydrogen gas is supplied through the inner fluid passage 174, while nitrogen gas is supplied through the outer fluid passage 175. Thus, the hydrogen gas to be fed through the inner fluid passage can be supplied from the hydrogen introducing pipe 17d, while being covered with the nitrogen gas.

### CROSS REFERENCE TO RELATED APPLICATIONS

This application is based upon the prior Japanese Patent Application No. 2006-278906 filed on Oct. 12, 2006, the entire contents of which are incorporated herein by reference.

### BACKGROUND OF THE INVENTION

1. Field of the Invention

The present invention relates to a gas supply system, a gas supply method, a method of cleaning a thin film forming apparatus, a thin film forming method and the thin film forming apparatus.

2. Background Art

In a manufacturing process for semiconductor devices, forming a thin film, such as a silicon nitride film, a silicon oxide film and the like, on each object to be processed, for example, a semiconductor wafer, by employing chemical vapor deposition (CVD) or the like, is currently a prevalent method. In such a thin film forming process, for example, a thin film is formed on each semiconductor wafer as described below.

First, the interior of a reaction vessel of a heating apparatus is heated to a predetermined loading temperature by using a heater, and a wafer boat containing multiple sheets of semiconductor wafers therein is then loaded in the reaction vessel. Subsequently, while heating the interior of the reaction vessel to a predetermined processing temperature by using the heater, a gas present in the reaction vessel is discharged through an exhaust pipe, so as to reduce the pressure in the reaction vessel to a predetermined value. Once the interior of the reaction vessel is kept at predetermined temperature and pressure, a film forming gas is supplied into the reaction vessel through a processing gas introducing pipe. After the film forming gas is supplied into the reaction vessel, the film forming gas generates, for example, a thermal reaction, and reaction products to be created by such a thermal reaction are then deposited on the surface of each semiconductor wafer, thus forming a thin film on the surface of the semiconductor wafer.

The reaction products to be created by the thin film forming process are deposited (or attached) not only onto the surface of each semiconductor wafer but also onto the interior of the heating apparatus, such as inner walls of the reaction vessel and/or various jigs. Additionally, by-products and/or intermediate products may also be created, and then attached to the interior of the reaction vessel and inner wall of the exhaust pipe. If continuing the thin film forming process with such deposits being attached to the interior of the heating apparatus, stress is generated due to the difference between the coefficient of thermal expansion of the quartz constituting the reaction vessel and that of the deposits, leading to breakage or cracking of the quartz and deposits. As a result, the so-broken or cracked quarts or deposits may tend to be particles, which may be attributed to deterioration of productivity. In addition, such phenomena may cause failures of components.

To address this problem, a cleaning method for the heating apparatus has been proposed, which comprises supplying a cleaning gas into the reaction vessel heated to a predetermined temperature by using the heater, thereby removing (or dry-etching) the reaction products attached or deposited onto the interior of the heating apparatus, such as inner walls of the reaction vessel (e.g., see Patent Document 1 and Patent Document 2).

Patent Document 1: TOKUKAIHEI No. 3-293726, KOHO

Patent Document 2: TOKUKAI No. 2003-59915, KOHO

Generally, a gas introducing pipe for introducing the cleaning gas is in communication with the interior of the reaction vessel for supplying each kind of gas therein. Thus, when utilizing a mixed gas, containing fluorine gas (F₂) and hydrogen gas (H₂), as the cleaning gas, the fluorine gas and the hydrogen gas are separately supplied into the reaction vessel. In this case, however, the fluorine gas to be supplied into the reaction vessel may be carried in the vicinity of a blowout port (or nozzle) of the gas introducing pipe for introducing the hydrogen gas, and thus react with the hydrogen gas around the nozzle. Once the fluorine gas reacts with the hydrogen gas in the vicinity of the nozzle, hydrogen fluoride (HF) is generated from the reaction, thus damaging and deteriorating components provided around the nozzle, such as nozzles of the gas introducing pipes and inner walls of the reaction vessel. This can not provide secure cleaning for the thin film forming apparatus.

### SUMMARY OF THE INVENTION

The present invention was made in light of the above problems, and therefore it is an object of this invention to provide a gas supply system, a gas supply method, a method of cleaning a thin film forming apparatus, a thin film forming method and the thin film forming apparatus, which can avoid or substantially eliminate such deterioration of components as described above.

Another object of this invention is to provide a gas supply system, a gas supply method, a method of cleaning a thin film forming apparatus, a thin film forming method and the thin film forming apparatus, which can provide secure cleaning for the thin film forming apparatus.

The present invention is a gas supply system for removing deposits attached to the interior of a thin film forming apparatus including a reaction chamber and an exhaust pipe connected with the reaction chamber, by supplying a cleaning gas, containing fluorine gas and hydrogen gas, into the reaction chamber of the thin film forming apparatus or into the exhaust pipe, the gas supply system comprising: a fluorine supply means for supplying the fluorine gas into the reaction chamber or into the exhaust pipe; and a hydrogen supply means for supplying the hydrogen gas into the reaction chamber or into the exhaust pipe, wherein the hydrogen supply means includes an inner fluid passage and an outer fluid passage formed to cover around the inner fluid passage, and wherein the hydrogen gas is supplied through the inner fluid passage, while a protective gas, which will not react with the fluorine gas to be supplied from the fluorine supply means, is supplied through the outer fluid passage, whereby the hydrogen gas can be supplied into the reaction chamber or into the exhaust pipe, while it is covered with the protective gas.

The present invention is the gas supply system described above, wherein the hydrogen supply means includes an inner pipe and an outer pipe formed to house the inner pipe therein, such that the inner fluid passage and outer fluid passage are formed of the inner pipe and outer pipe, respectively.

The present invention is the gas supply system described above, wherein the hydrogen supply means is configured, such that the hydrogen gas is supplied, at 0.25 litters/min to 0.75 litters/min, through the inner fluid passage, and such that the nitrogen gas is supplied, at 1 litter/min to 5 litters/min, through the outer fluid passage.

The present invention is the gas supply system described above, wherein the ratio of cross-sectional areas of the inner fluid passage and the outer fluid passage is within a range from 1:2 to 1:4.

The present invention is the gas supply system described above, wherein the protective gas is nitrogen gas.

The present invention is a thin film forming apparatus, comprising: a reaction chamber into which an object to be processed is loaded and a film forming gas is then supplied, so as to form a thin film on the object to be processed; an exhaust pipe connected with the reaction chamber; and a gas supply system for supplying a cleaning gas containing fluorine gas and hydrogen gas into the reaction chamber or into the exhaust pipe, wherein the gas supply system includes: a fluorine supply means for supplying the fluorine gas into the reaction chamber or into the exhaust pipe; a hydrogen supply means for supplying the hydrogen gas into the reaction chamber or into the exhaust pipe, wherein the hydrogen supply means includes an inner fluid passage and an outer fluid passage formed to cover around the inner fluid passage, and wherein the hydrogen gas is supplied through the inner fluid passage, while a protective gas, which will not react with the fluorine gas to be supplied from the fluorine supply means, is supplied through the outer fluid passage, whereby the hydrogen gas can be supplied into the reaction chamber or into the exhaust pipe, while it is covered with the protective gas.

The present invention is a gas supply method for removing deposits attached to the interior of a thin film forming apparatus including a reaction chamber and an exhaust pipe connected with the reaction chamber, by supplying a cleaning gas, containing fluorine gas and hydrogen gas, into the reaction chamber of the thin film forming apparatus or into the exhaust pipe, the gas supply method comprising the steps of: supplying the fluorine gas into the reaction chamber or into the exhaust pipe from a fluorine supply means for supplying the fluorine gas; and supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is the gas supply method described above, wherein in the step of supplying the hydrogen gas, the hydrogen gas is supplied, at 0.25 litters/min to 0.75 litters/min, through the inner fluid passage, and the nitrogen gas is supplied, at 1 litter/min to 5 litters/min, through the outer fluid passage.

The present invention is the gas supply method described above, wherein the protective gas is nitrogen gas.

The present invention is a method of cleaning a thin film forming apparatus including a reaction chamber and an exhaust pipe connected with the reaction chamber, for removing deposits attached to the interior of the thin film forming apparatus, the method comprising: a gas supply method for supplying a cleaning gas, containing fluorine gas and hydrogen gas, into the reaction chamber of the thin film forming apparatus or into the exhaust pipe, in order to remove the deposits attached to the interior of the thin film forming apparatus, the gas supply method comprising the steps of: supplying the fluorine gas into the reaction chamber or into the exhaust pipe from a fluorine supply means for supplying the fluorine gas; and supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is a thin film forming method, comprising the steps of: forming a thin film on each object to be processed by a thin film forming apparatus including a reaction chamber and an exhaust pipe connected with the reaction chamber, by supplying a film forming gas into a reaction chamber; and cleaning, due to a gas supply method for supplying a cleaning gas containing fluorine gas and hydrogen gas, into the reaction chamber or into the exhaust pipe, in order to remove deposits attached to the interior of the thin film forming apparatus, the gas supply method comprising the steps of: supplying the fluorine gas into the reaction chamber or into the exhaust pipe from a fluorine supply means for supplying the fluorine gas; and supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is a computer program for driving a computer to perform a gas supply method for removing deposits attached to the interior of a thin film forming apparatus including a reaction chamber and an exhaust pipe connected with the reaction chamber, by supplying a cleaning gas containing fluorine gas and hydrogen gas, into the reaction chamber of the thin film forming apparatus or into the exhaust pipe, the gas supply method comprising the steps of: supplying the fluorine gas into the reaction chamber or into the exhaust pipe from a fluorine supply section for supplying the fluorine gas; and supplying the hydrogen gas into the reaction chamber or into the exhaust pipe from a hydrogen supply section including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is a storage medium for storing a computer program for driving a computer to perform a gas supply method for removing deposits attached to the interior of a thin film forming apparatus including a reaction chamber and an exhaust pipe connected with the reaction chamber, by supplying a cleaning gas containing fluorine gas and hydrogen gas, into the reaction chamber of the thin film forming apparatus or into the exhaust pipe, the gas supply method comprising the steps of: supplying the fluorine gas into the reaction chamber or into the exhaust pipe from a fluorine supply section for supplying the fluorine gas; and supplying the hydrogen gas into the reaction chamber or into the exhaust pipe from a hydrogen supply section including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is a computer program for driving a computer to perform a method of cleaning a thin film forming apparatus including a reaction chamber and an exhaust pipe connected with the reaction chamber, for removing deposits attached to the interior of the thin film forming apparatus, the method of cleaning the thin film forming apparatus comprising: a gas supply method for supplying a cleaning gas, containing fluorine gas and hydrogen gas, into the reaction chamber of the thin film forming apparatus or into the exhaust pipe, in order to remove deposits attached to the interior of the thin film forming apparatus, the gas supply method comprising the steps of: supplying the fluorine gas into the reaction chamber or into the exhaust pipe from a fluorine supply means for supplying the fluorine gas; and supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

The present invention is a storage medium for storing a computer program for driving a computer to perform a method of cleaning a thin film forming apparatus including a reaction chamber and an exhaust pipe connected with the reaction chamber, for removing deposits attached to the interior of the thin film forming apparatus, the method of cleaning the thin film forming apparatus comprising: a gas supply method for supplying a cleaning gas, containing fluorine gas and hydrogen gas, into the reaction chamber of the thin film forming apparatus or into the exhaust pipe, in order to remove the deposits attached to the interior of the thin film forming apparatus, the gas supply method comprising the steps of: supplying the fluorine gas into the reaction chamber or into the exhaust pipe from a fluorine supply means for supplying the fluorine gas; and supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

According to the present invention, degradation of parts or components can be suppressed.

### BRIEF DESCRIPTION OF THE DRAWINGS

FIG. 1 is a view showing a heating apparatus of one embodiment according to the present invention.

FIG. 2 is a diagram showing a construction of a gas supply section shown in FIG. 1.

FIG. 3 is a view showing a cross-sectional shape of a hydrogen introducing pipe.

FIG. 4 is a view illustrating a manner of supplying hydrogen gas and nitrogen gas from the hydrogen introducing pipe.

FIG. 5 is a diagram showing a construction of a control section shown in FIG. 1.

FIG. 6 is a diagram showing a recipe for explaining a thin film forming method.

FIG. 7 is a view illustrating a position of a quartz chip.

FIG. 8 is a diagram showing an etching rate for the quartz located in the position shown in FIG. 7.

FIG. 9 is a diagram showing etching rates for SiN and quartz in a cleaning process.

FIG. 10 is a diagram showing a selection ratio in the cleaning process.

FIG. 11 is a view showing the heating apparatus of another embodiment.

### DETAILED DESCRIPTION OF THE INVENTION

### Examples

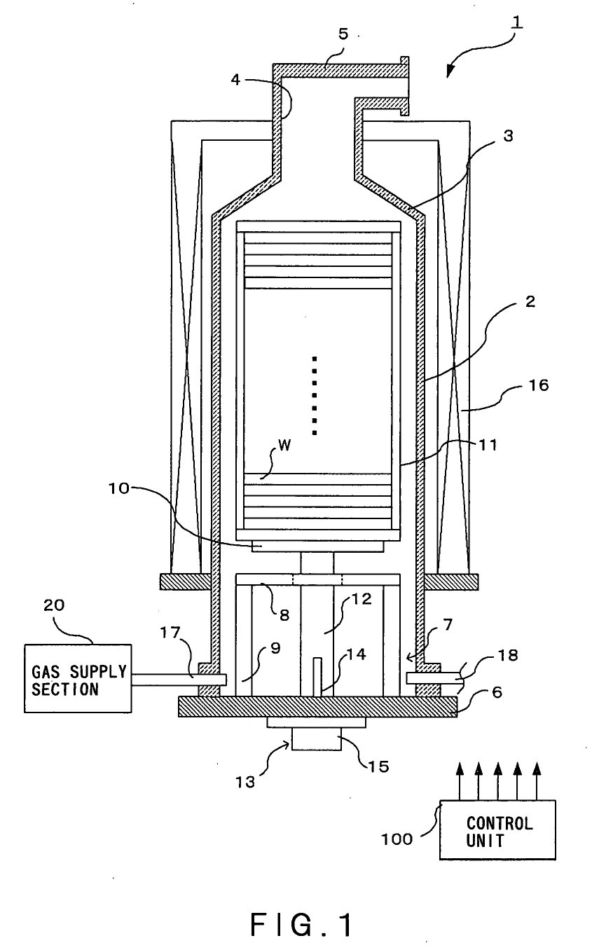

Hereinafter, a gas supply system, a gas supply method, a method of cleaning a thin film forming apparatus, a thin film forming method and the thin film forming apparatus, according to the present invention, will be described. In one embodiment, the present invention will be described, by way of example, with respect to a batch-and-vertical-type heating apparatus 1 shown in FIG. 1, as a thin film forming apparatus including a gas supply system.

As shown in FIG. 1, the heating apparatus 1, as the thin film forming apparatus, includes a reaction vessel 2 constituting a reaction chamber, and an exhaust pipe 5 connected with an upper portion of the reaction vessel 2.

The reaction vessel 2 is formed to have a substantially cylindrical shape with a longitudinal direction oriented in the vertical direction. The reaction vessel 2 is formed from a material, for example, quartz, which is superior in both of the heat resistance and the corrosion resistance. At an upper end of the reaction vessel 2, an apex portion 3 is provided, which is formed to have a substantially conical shape tapered toward the top end. An exhaust port 4 is provided in a central portion of the apex portion 3, for discharging a gas in the reaction vessel 2, and the aforementioned exhaust pipe 5 is connected airtightly to the exhaust port 4. Along with the exhaust pipe 5, a pressure control mechanism, such as a valve (not shown) and/or a vacuum pump 127, is provided for adjusting the pressure in the reaction vessel 2 at a desired value (or degree of vacuum).

A cover 6 is disposed below the reaction vessel 2. The cover 6 is formed from a material, such as quartz, which is superior in both of the heat resistance and the corrosion resistance. The cover 6 is configured to be optionally moved in the vertical direction by a boat elevator 128 as will be described below. When the cover 6 is raised by the boat elevator 128, a lower portion (or furnace port portion) of the reaction vessel 2 is closed, while when the cover 6 is lowered by the boat elevator 128, the lower portion (or furnace port portion) of the reaction vessel 2 is opened.

At an upper portion of the cover 6, a heat insulating mound 7 is provided. The heat insulating mound 7 is generally composed of a flat heater 8 formed of a resistive heating element for preventing temperature decrease in the reaction vessel 2 due to heat radiation from the furnace port of the reaction vessel 2, and a tubular support member 9 for supporting the heater 8 at a predetermined level from a top face of the cover 6.

A rotary table 10 is provided above the heat insulating mound 7. The rotary table 10 serves as a table for rotatably placing a wafer boat 11 thereon, while the wafer boat 11 containing objects to be processed, such as semiconductor wafers W. Specifically, a rotary post 12 is provided at a bottom portion of the rotary table 10, extends through a central portion of the heater 8, and is connected to a rotary mechanism 13 for rotating the rotary table 10. The rotary mechanism 13 generally includes of a motor (not shown) and a rotation introducing section 15 including a rotary shaft 14 airtightly inserted through the cover 6 from its bottom face side to its top face side. The rotary shaft 14 is connected to the rotary post 12 of the rotary table 10 in order to transmit the rotational force of the motor to the rotary table 10 via the rotary post 12. Thus, when the rotary shaft 14 is rotated by the motor of the rotary mechanism 13, the rotational force of the rotary shaft 14 is transmitted to the rotary post 12, thereby rotating the rotary table 10.

The wafer boat 11 is configured to contain a plurality of semiconductor wafers W therein, with each semiconductor wafer W being arranged at a predetermined interval in the vertical direction. The wafer boat 11 is formed of, for example, quartz. The wafer boat 11 is placed on the rotary table 10. As such, when the rotary table 10 is rotated, the wafer boat 11 is also rotated, thereby rotating the semiconductor wafers W contained in the wafer boat 11.

Around the reaction vessel 2, a temperature rising heater 16 formed of, for example, a resistive heating element, is provided to surround the reaction vessel 2. Due to the temperature rising heater 16, the interior of the reaction vessel 2 is heated to a predetermined temperature, as such the semiconductor wafers W are heated to the predetermined temperature.

A processing gas introducing pipe 17 and a gas supply section 20 are connected with a side face in the vicinity of a lower end of the reaction vessel 2.

The processing gas introducing pipe 17 is connected with a side wall in the vicinity of the lower end of the reaction vessel 2, in order to introduce a processing gas supplied from the gas supply section 20 into the reaction vessel 2. A nozzle (or blowout port) of the processing gas introducing pipe 17 is formed of a material, for example, quartz, which is superior in both of the heat resistance and the corrosion resistance. While only one processing gas introducing pipe 17 is drawn in FIG. 1, in this embodiment, a plurality of processing gas introducing pipes 17 are provided, one for each processing gas.

As the processing gas to be introduced into the reaction vessel 2, a cleaning gas for removing (or cleaning) deposits (reaction products or the like) attached to the interior of the heating apparatus 1 can be mentioned. In this embodiment, a film forming gas for forming a thin film on each semiconductor wafer W is also included in the concept of the processing gas to be supplied into the reaction vessel 2.

The cleaning gas of this invention comprises fluorine gas and hydrogen gas. In this embodiment, the cleaning gas essentially consists of a mixed gas of the fluorine gas, hydrogen gas, and nitrogen gas as a protective gas. The term, “protective gas”, refers to, as will be described below, a gas for surrounding or wholly covering the hydrogen gas in order to prevent (or protect) the hydrogen gas from reacting with the fluorine gas in the vicinity of the nozzle.

As the film forming gas of this invention, a gas that is able to form a thin film can be used, wherein deposits to be formed from the gas and attached to the inner walls or the like of the reaction vessel 2 during the film forming process can be removed by the cleaning gas. As the film forming gas, dichlorosilane (DCS: SiH₂Cl₂) and ammonia (NH₃), and/or hexachlorodisilane (HCD: Si₂Cl₆) and ammonia (NH₃) are known, and a silicon nitride film is formed on each semiconductor wafer W by using such a film forming gas. The film forming gas of this embodiment comprises a mixed gas containing dichlorosilane and ammonia.

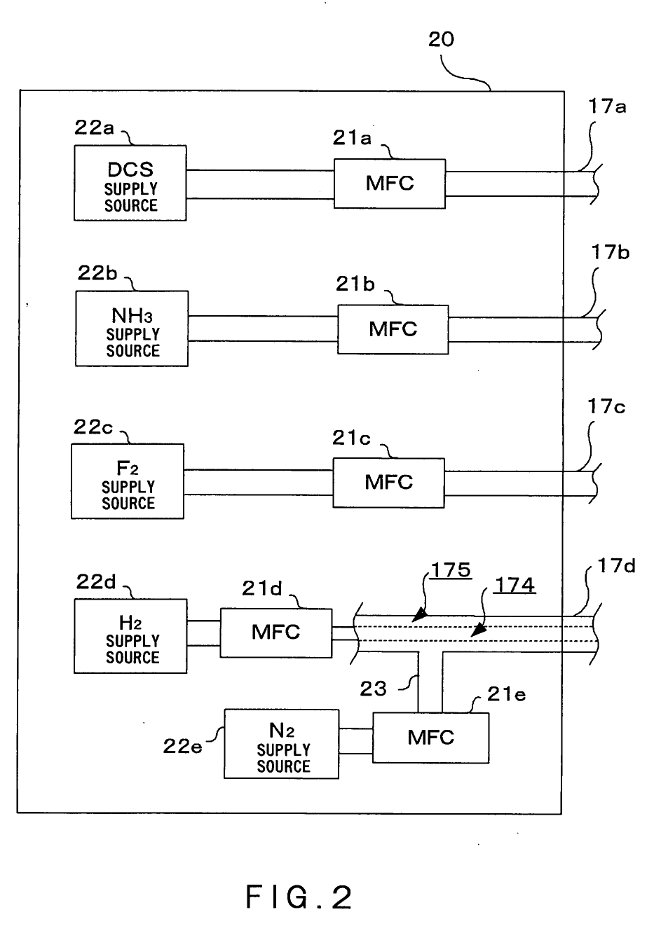

To the reaction vessel 2, as shown in FIG. 2, four processing gas introducing pipes 17, i.e., a dichlorosilane introducing pipe 17a for introducing dichlorosilane, an ammonia introducing pipe 17b for introducing ammonia, a fluorine introducing pipe 17c for introducing the fluorine gas, and a hydrogen introducing pipe 17d for introducing the hydrogen gas, are provided.

The construction of the gas supply section 20 is shown in FIG. 2. As shown in FIG. 2, mass flow controllers (MFC) 21 (21a to 21c) as flow rate controlling units, and gas supply sources 22 (22a to 22c) are provided to the dichlorosilane introducing pipe 17a, ammonia introducing pipe 17b and fluorine introducing pipe 17c, respectively. Each MFC 21 controls the flow rate of the gas flowing through each processing gas pipe 17a to 17c. Each gas supply source 22 is provided at an end point of each processing gas introducing pipe 17a to 17c, containing the processing gas (dichlorosilane, ammonia or fluorine gas) to be supplied into the reaction vessel 2 (via each processing gas introducing pipe 17a to 17c). Thus, the processing gas to be supplied from each gas supply source 22 can be introduced into the reaction vessel 2 via each MFC 21. In this embodiment, a 20% fluorine gas diluted with nitrogen gas is supplied through the processing gas introducing pipe 17c.

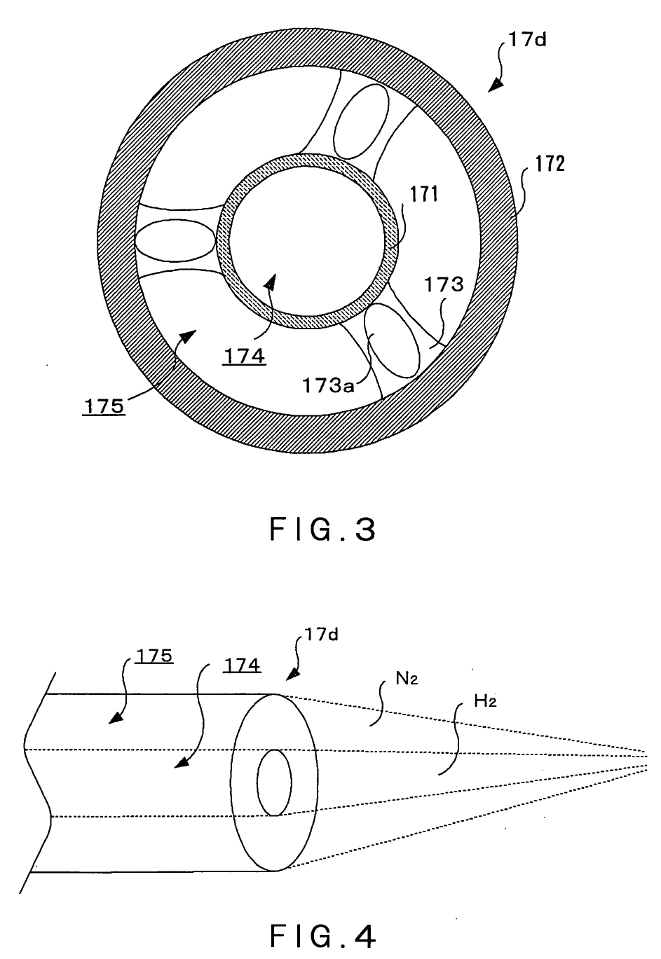

The hydrogen introducing pipe 17d has a double-pipe structure. FIG. 3 shows a shape of the cross section of the hydrogen introducing pipe 17d. As shown in FIG. 3, the hydrogen introducing pipe 17d includes an inner pipe 171, an outer pipe 172, and connecting portions 173 for connecting the inner pipe 171 with the outer pipe 172 so as to hold the inner tube 171 in place. Specifically, the connecting portions 173 hold the inner pipe 171, such that the gas fed through the inner pipe 171 can be supplied into the reaction vessel 2, while being surrounded or wholly covered with the gas fed through the outer pipe 172. The connecting portions 173 are configured to connect the inner pipe 171 with the outer pipe 172 so as to hold the inner pipe 171 at a point other than the blowout port of the hydrogen introducing pipe 17d. This is because, if providing the connecting portions 173 at the blowout port, a resultant gas supplied from an outer fluid passage 175, which will be described below, would be divided into parts. The connecting portions 173 may be formed only in the vicinity of an end portion of the hydrogen introducing pipe 17d, or otherwise may be formed at predetermined intervals through the hydrogen introducing pipe 17d. In this embodiment, the connecting portions 173 are provided in the vicinity of the end portion of the hydrogen introducing pipe 17d so as to hold the inner pipe 171 at three points while creating through holes 173a between the respective members. Constructed in such a manner, the hydrogen introducing pipe 17d should include an inner fluid passage 174 and the outer fluid passage 175 therein. However, each of the dichlorosilane introducing pipe 17a, ammonia introducing pipe 17b and fluorine introducing pipe 17c has a single pipe structure to supply the predetermined processing gas therethrough.

The inner pipe 171 of the hydrogen introducing pipe 17d is connected with the gas supply source 22d that is a supply source of the hydrogen gas, via the MFC 21d. To the external pipe 172 of the hydrogen introducing pipe 17d, a connecting pipe 23 is connected. The connecting pipe 23 is further connected with a gas supply source 22e that is a supply source of the protective gas, via an MFC 21e. The protective gas does not react with the fluorine gas, and will not detrimentally affect the cleaning. In this embodiment, nitrogen gas is used as the protective gas. As such, the hydrogen gas is supplied through the inner fluid passage 174 of the hydrogen introducing pipe 17d and the nitrogen gas is supplied through the outer fluid passage 175.

Upon supplying the hydrogen gas and the nitrogen gas into the reaction vessel 2 from the hydrogen introducing pipe 17d constructed as described above, the hydrogen (H₂) gas fed through the inner fluid passage 174 is supplied into the reaction vessel 2 while being wholly covered with the nitrogen (N₂) gas fed through the outer fluid passage 175. Thus, even though the fluorine gas fed through the fluorine introducing pipe 17c is present in the vicinity of the nozzle of the hydrogen introducing pipe 17d, it will not react with the hydrogen gas. Accordingly, the nozzle of the hydrogen introducing pipe 17d and components located in the vicinity of the nozzle, such as the inner walls of the reaction vessel 2, will not be subjected to damage, thereby providing more stable cleaning of the heating apparatus 1.

It should be appreciated that the shape of the hydrogen introducing pipe 17d may take any given one, depending on the flow rates of the hydrogen and nitrogen gases, the position of the fluorine introducing pipe 17c, and the like, provided that it is formed to bring the hydrogen gas supplied from the inner fluid passage 174 into a surrounded or wholly covered state due to the nitrogen gas supplied from the outer fluid passage 175, in the vicinity of the nozzle of the hydrogen introducing pipe 17d.

The ratio of the cross-sectional areas of inner fluid passage 174 and outer fluid passage 175 may be within a suitable range, such that the hydrogen gas is surrounded or wholly covered with the nitrogen gas in the vicinity of the nozzle of the hydrogen introducing pipe 17d, and such that the hydrogen gas can be exposed in a suitable place, for example, around an intermediate point between the nozzle of the hydrogen introducing pipe 17d and the rotary post 12. Generally, as the cross-sectional ratio of the outer fluid passage 175 is decreased, it becomes difficult to sufficiently cover around the hydrogen gas with the nitrogen gas to be supplied from the outer fluid passage 175. Contrary, as the cross-sectional ratio of the outer fluid passage 175 is increased, it becomes difficult to bring the hydrogen gas exposed in a suitable place. Preferably, the ratio of the cross-sectional areas of inner fluid passage 174 and outer fluid passage 175 is 1:2 to 1:4, more preferably around 1:3.

As shown in FIG. 1, a purge gas supply pipe 18 is provided through a side wall in the vicinity of the bottom end of the reaction vessel 2. To the purge gas supply pipe 18, a purge gas supply source (not shown) is connected, such that a desired amount of a purge gas, for example, nitrogen gas, can be supplied into the reaction vessel 2.

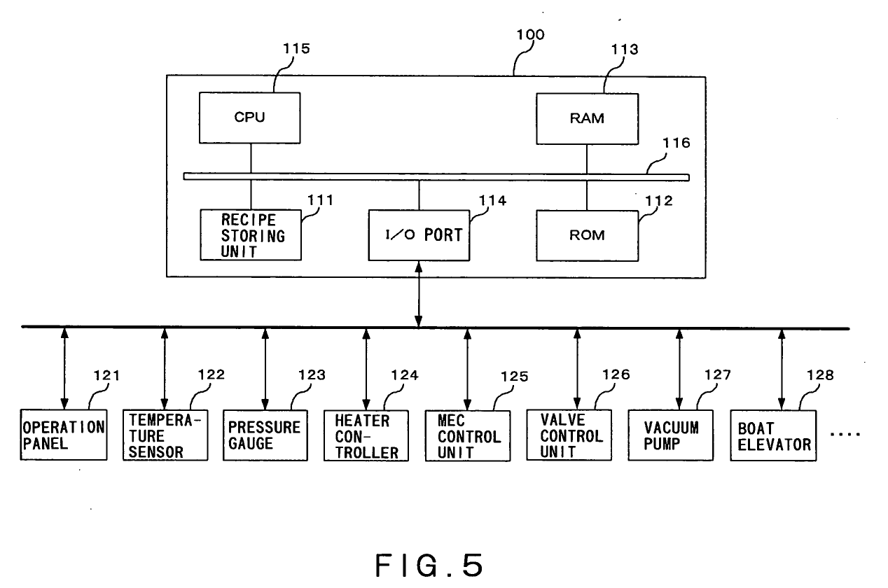

The heating apparatus 1 also includes a control unit 100 for controlling each section of the apparatus. FIG. 5 shows the construction of the controlling unit 100. As shown in FIG. 5, to the control unit 100, an operation panel 121, a temperature sensor (or group of the sensors) 122, a pressure gauge (or group of the gauges) 123, a heater controller 124, an MFC control unit 125, the valve control unit 126, the vacuum pump 127, and the like are connected.

The operation panel 121 includes a display screen and operation buttons, communicates an operator's indication to the control unit 100, and displays a variety of information given from the control unit 100 on the display screen.

The temperature sensor (or group of the sensors) 122 measures temperature in the reaction vessel 2, exhaust pipe 5, processing gas introducing pipes 17 and the like, and communicates the measured values to the control unit 100.

The pressure gauge (or group of the gauges) 123 measures pressure in the reaction vessel 2, exhaust pipes 5, processing gas introducing pipes 17 and the like, and communicates the measured values to the control unit 100.

The heater controller 124 is used for individually controlling the heater 8 and the temperature rising heater 16, and is configured to heat these heaters by individually applying currents thereto, in response to indications given from the control unit 100. Further, the heater controller 124 measures the electric power consumption of these heaters, individually, and communicates the measured data to the control unit 100.

The MFC control unit 125 is used for controlling the MFC 21a to 21e respectively provided in the processing gas introducing pipes 17 and an MFC (not shown) provided in the purge gas supply pipe 18, such that the flow rates of the gases flowing through these MFC are adjusted at amounts respectively indicated by the control unit 100. In addition, the MFC control unit 125 measures the flow rates of actually flowing gases, and communicates the measured data to the control unit 100.

The valve control unit 126 controls degrees of opening valves disposed at the respective pipes in accordance with values respectively indicated by the control unit 100. The vacuum pump 127 is connected with the exhaust pipe 5, and is adapted to discharge the gas present in the reaction vessel 2.

The boat elevator 128 takes the wafer boat 11 (or semiconductor wafers W) placed on the rotary table 10 into the reaction vessel 2 by elevating the cover 6, and takes the wafer boat 11 (or semiconductor wafers W) placed on the rotary table 10 from the reaction vessel 2 by lowering the cover 6.

The control unit 100 includes a recipe storing unit 111, a ROM 112, a RAM 113, an I/O port 114, a CPU 115, and a bus 116 for mutually connecting these units.

In the recipe storing unit 111, a setup recipe and a plurality of process recipes are stored. On the stage of producing the heating apparatus 1, only the setup recipe is stored. The setup recipe is one to be executed upon producing a thermal model or the like corresponding to each heating apparatus. The process recipes are used for each heating process to be actually performed by a user. Namely, the process recipes are provided for prescribing temperature changes for each section, pressure changes in the reaction vessel 2, timings of starting and ending the supply of each processing gas and its supply amount, and the like, during a period of time, for example, from the loading of semiconductor wafers W into the reaction vessel 2 to the unloading of processed wafers W.

The ROM 112 is composed of an EEPROM, a flash memory, a hard disk, or the like, and is used as a storage medium for storing an operational program of the CPU 115. The RAM 113 serves as a working area for the CPU 115 or the like.

The I/O port 114 is connected to the operation panel 121, temperature sensor 122, pressure gauge 123, heater controller 124, MFC control unit 125, valve control unit 126, vacuum pump 127 and boat elevator 128, and controls input and output of data and signals.

The CPU (Central Processing Unit) 115 is a key section of the control unit 100, and executes a control program stored in the ROM 112, so as to control the operation of the heating apparatus 1, following the recipes (process recipes) stored in the recipe storing unit 111, in accordance with the indication from the operation panel 121. Namely, the CPU 115 causes the temperature sensor (or group of the sensors) 122, pressure gauge (or group of the gauges) 123, MFC control unit 125 and the like to measure the temperature, pressure, flow rates or the like, in the reaction vessel 2, processing gas introducing pipes 17 and exhaust pipe 5. Thereafter, the CPU 115 outputs control signals or the like, based on the measured data, to the heater controller 124, MFC control unit 125, valve control unit 126, vacuum pump 127, and the like, so as to control each section or unit to follow the respective process recipes.

The bus 116 serves to communicate information between the respective sections or units.

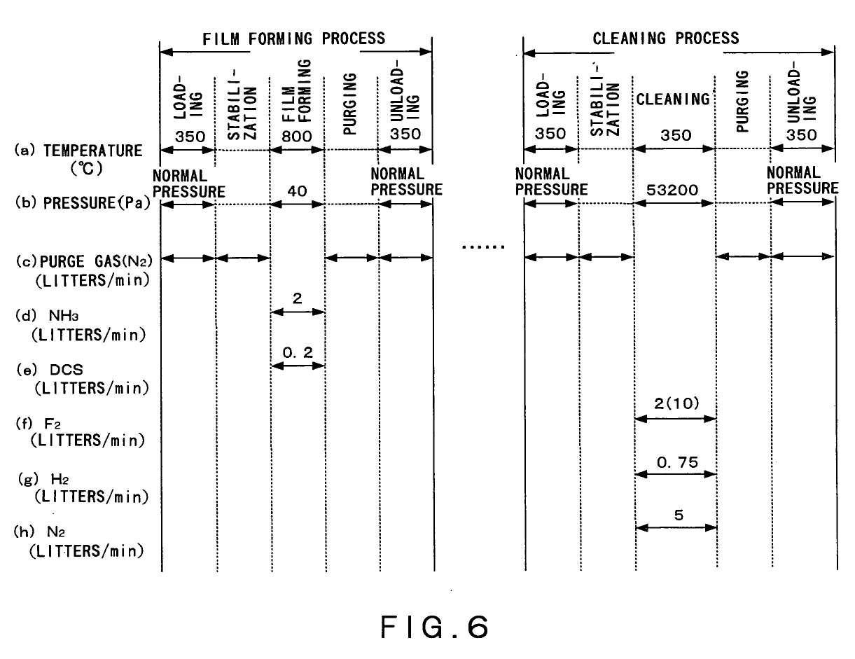

Next, the gas supply method, method of cleaning the thin film forming apparatus and thin film forming method will be described, with respect to the heating apparatus 1 (the film forming apparatus including the gas supply system according to the present invention) constructed as discussed above. FIG. 6 shows recipes provided for explaining the thin film forming method of this embodiment.

In this embodiment, the present invention is described with respect to a case wherein the DCS (SiH₂Cl₂) and ammonia (NH₃) are supplied to the semiconductor wafers W so as to form a silicon nitride film having a predetermined thickness on each semiconductor wafer W, and thereafter deposits (silicon nitride) attached to the interior of the heating apparatus 1 is removed. In the description provided below, the operation of each section or unit constituting the heating apparatus 1 is controlled by the control unit 100 (CPU 115). The temperature, pressure and gas flow rate in the reaction vessel 2 for each process is determined, under conditions based on the recipes shown in FIG. 6, due to the control section 100 (CPU 115), by controlling the heater controller 124 (for the heater 8 and/or temperature rising heater 16), MFC control unit 125 (for the MFC 21 and the like), valve control unit 126, vacuum pump 127 and the like.

First, for instance, as shown in FIG. 6(a), the temperature in the reaction vessel 2 is set at, for example, 350° C. As shown in FIG. 6(c), a predetermined amount of the purge gas (nitrogen) is supplied into the reaction vessel 2 from the purge gas supply pipe 18, and the wafer boat 11 is placed on the cover 6 with the semiconductor wafers W, as the objects to be processed to form silicon nitride films thereon, contained in the wafer boat 11. Thereafter, the cover 6 is elevated by actuating the boat elevator 128, so as to load the semiconductor wafers W (or wafer boat 11) into the reaction vessel 2 (loading step).

Subsequently, as shown in FIG. 6(c), a predetermined amount of nitrogen gas is supplied into the reaction vessel 2 from the purge gas supply pipe 18, while the temperature in the reaction vessel 2 is set at a predetermined value, for instance, 80° C., as shown in FIG. 6(a). Thereafter, by discharging the gas present in the reaction vessel 2, the pressure in the reaction vessel 2 is reduced to a predetermined value, for instance, 40 Pa (0.3 Torr), as shown in FIG. 6(b). In addition, the pressure and temperature in the reaction vessel 2 are controlled until the reaction vessel 2 is stabilized to have predetermined pressure and temperature (stabilizing step). Once the interior of the reaction vessel 2 is stabilized at the predetermined pressure and temperature, the supply of nitrogen gas from the purge gas supply pipe 18 is stopped.

Thereafter, the film forming gas is introduced into the reaction vessel 2 through the processing gas introducing pipes 17 (the dichlorosilane introducing pipe 17a and ammonia introducing pipe 17b). In this embodiment, as shown in FIG. 6(d), the ammonia is supplied at 2 litters/min, by controlling the MFC 21b, and as shown in FIG. 6(e), the DCS is supplied at 0.2 litters/min, by controlling the MFC 21a. Consequently, the film forming gas having been introduced in the reaction vessel 2 is heated therein, and the silicon nitride film is thus formed on the surface of each semiconductor wafer W (film forming step).

Once the silicon nitride film having a predetermined thickness is formed on the surface of each semiconductor wafer W, the introduction of the film forming gas from the dichlorosilane introducing pipe 17a and ammonia introducing pipe 17b is stopped. Subsequently, while discharging the gas from the reaction vessel 2, a predetermined amount of nitrogen gas is supplied from the purge gas supply pipe 18, as shown in FIG. 6(c), so as to discharge the gas present in the reaction vessel 2 into the exhaust pipe 5 (purging step). It is preferred to repeat the gas discharge from the reaction vessel 2 and the supply of nitrogen gas several times in order to securely discharge the gas present in the reaction vessel 2.

Subsequently, as shown in FIG. 6(c), a predetermined amount of nitrogen gas is supplied into the reaction vessel 2 from the purge gas supply pipe 18, such that, as shown in FIG. 6(b), the pressure in the reaction vessel 2 is returned to a normal pressure. The interior of the reaction vessel 2 is set at, for example, 350° C., as shown in FIG. 6(a). Thereafter, by lowering the cover 6 by driving the boat elevator 128, the semiconductor wafers W (or wafer boat 11) are unloaded from the reaction vessel 2 (unloading step). In this manner, the film forming process is ended.

By repeating such a film forming process many times, silicon nitride to be produced in the film forming process should be deposited (or attached) not only on the surface of each semiconductor wafer W but also to the inner walls of the reaction vessel 2. Therefore, a cleaning process (the cleaning method for the thin film forming apparatus of this invention) must be conducted after repeating the film forming process predetermined times.

First, the interior of the reaction vessel 2 is set at, for example, 350° C., as shown in FIG. 6(a). Thereafter, as shown in FIG. 6(c), a predetermined amount of nitrogen gas is supplied into the reaction vessel 2 through the purge gas supply pipe 18, and the vacant wafer boat 11 containing no semiconductor wafers W therein is placed on the cover 6. Then, the cover 6 is elevated by actuating the boat elevator 128, thus loading the wafer boat 11 into the reaction vessel 2 (loading step).

Subsequently, as shown in FIG. 6(c), a predetermined amount of nitrogen gas is supplied from the purge gas supply pipe 18, while the interior of the reaction vessel 2 is set at, for example, 350° C., as shown in FIG. 6(a). Thereafter, the gas present in the reaction vessel 2 is discharged, and the pressure in the reaction vessel 2 is reduced to a predetermined value, for example, 53200 Pa (400 Torr), as shown in FIG. 6(b). In addition, the pressure and temperature in the reaction vessel 2 are controlled until the reaction vessel 2 is stabilized to have predetermined pressure and temperature (stabilizing step). Once the interior of the reaction vessel 2 is stabilized at the predetermined pressure and temperature, the supply of nitrogen gas from the purge gas supply pipe 18 is stopped.

Thereafter, the cleaning gas is introduced into the reaction vessel 2 through the processing gas introducing pipes 17 (the fluorine introducing pipe 17c and hydrogen introducing pipe 17d). In this embodiment, as shown in FIG. 6(f), the fluorine (F₂) gas is supplied at 10 litters/min, through the fluorine introducing pipe 17c, by controlling the MFC 21c. In this embodiment, a 20% fluorine gas diluted with nitrogen gas is used as the fluorine gas, and the flow rate of the fluorine gas is 2 litters/min. Besides, as shown in FIG. 6(g), the hydrogen (H₂) gas is supplied through the inner fluid passage 174 of the hydrogen introducing pipe 17d, at 0.75 litters/min, by controlling the MFC 21d, while as shown in FIG. 6(h), the nitrogen (N₂) gas as the diluting gas is supplied through the outer fluid passage 175 of the hydrogen introducing pipe 17d, at 5 litters/min, by controlling the MFC 21e.

In this way, since the hydrogen gas is supplied through the inner fluid passage 174 of the hydrogen introducing pipe 17d and the nitrogen gas is supplied through the outer fluid passage 175, the hydrogen gas fed though the inner fluid passage 174 is supplied into the reaction vessel 2 while being surrounded or wholly covered with the nitrogen (N₂) gas supplied through the outer fluid passage 175. Thus, the hydrogen and fluorine will not react with each other in the vicinity of the nozzle of the hydrogen introducing pipe 17d. Accordingly, the nozzle of the hydrogen introducing pipe 17d and components located in the vicinity of the nozzle, such as the inner walls of the reaction vessel 2, will not be subjected to damage, thereby providing more stable cleaning of the heating apparatus 1.

It is preferred that the flow rate of the hydrogen gas supplied through the inner fluid passage 174 is within a range of 0.25 litters/min to 0.75 litters/min. If it is less than 0.25 litters/min, the silicon nitride produced is not likely to be etched. Contrary, if greater than 0.75 litters/min, the hydrogen gas may not be wholly covered with the nitrogen gas to be supplied through the outer fluid passage 175, thus causing risk that the hydrogen and fluorine will react with each other in the vicinity of the nozzle of the hydrogen introducing pipe 17d.

It is preferred that the flow rate of the nitrogen gas supplied through the outer fluid passage 175 is within a range of 1 litter/min to 5 litters/min. If it is less than 1 litter/min, the hydrogen gas may not be wholly surrounded by the nitrogen gas supplied through the outer fluid passage 175, as such causing risk that the hydrogen and fluorine will react with each other in the vicinity of the nozzle of the hydrogen introducing pipe 17d. Contrary, if greater than 5 litters/min, it may be difficult to expose the hydrogen gas in an appropriate place as described above. More preferably, the flow rate of the nitrogen gas supplied through the outer fluid passage 175 is within the range of 2 litters/min to 3 litters/min.

Thereafter, the cleaning gas supplied into the reaction vessel 2 is heated therein, and the fluorine contained in the cleaning gas is activated. The so-activated fluorine is then in contact with the deposits (silicon nitride) attached to the interior of the heating apparatus 1, thereby to etch the silicon nitride. Consequently, the deposits attached to the interior of the heating apparatus 1 can be removed (cleaning step).

Once the deposits attached to the interior of the heating apparatus 1 are removed, the supply of the cleaning gas through the fluorine introducing pipe 17c and hydrogen introducing pipe 17d is stopped. Subsequently, while discharging the gas from the reaction vessel 2, a predetermined amount of nitrogen gas is supplied from the purge gas supply pipe 18, as shown in FIG. 6(c), so as to discharge the gas present in the reaction vessel 2 into the exhaust pipe 5 (purging step). It is preferred to repeat the gas discharge from the reaction vessel 2 and the supply of nitrogen gas several times in order to securely discharge the gas present in the reaction vessel 2.

Subsequently, as shown in FIG. 6(c), a predetermined amount of nitrogen gas is supplied into the reaction vessel 2 from the purge gas supply pipe 18, such that, as shown in FIG. 6(b), the pressure in the reaction vessel 2 is returned to a normal pressure. Finally, the unloading operation is conducted by lowering the cover 6 by actuating the boat elevator 128 (unloading step). In this manner, the cleaning process is ended.

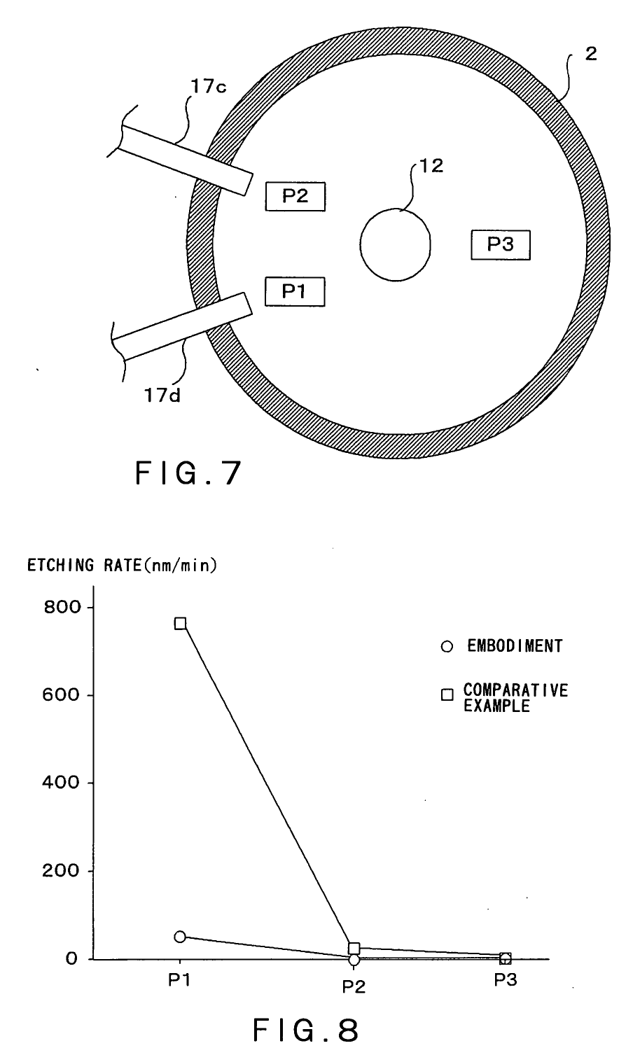

The efficacy of controlling damage or degradation of parts or components located in the vicinity of the nozzle of the hydrogen introducing pipe 17d after the cleaning process was examined. Specifically, as shown in FIG. 7, quartz chips were placed in a position P1 around the nozzle of the hydrogen introducing pipe 17d, a position P2 around the nozzle of the fluorine introducing pipe 17c, and a position P3 opposed to these processing gas introducing pipes 17, respectively, in the reaction vessel 2. Under the conditions of the embodiment described above, the etching rate for the quartz was measured. For comparison, the etching rate was measured also in the case (Comparative Example) where a mixed gas consisting of hydrogen and nitrogen was supplied to the interior, by using the hydrogen introducing pipe 17d having a single-pipe structure as the dichlorosilane introducing pipe 17a or the like, as is conventional. The results are shown in FIG. 8.

As shown in FIG. 8, by supplying the hydrogen gas through the inner fluid passage 174 and by supplying the nitrogen gas through the outer fluid passage 175, due to the hydrogen introducing pipe 17d having the double-pipe structure, it was found that the damage to be generated around the nozzle of the hydrogen introducing pipe 17d could be significantly reduced, as compared with the conventional single-pipe structure. Thus, according to the present invention, more stabilized cleaning for the heating apparatus 1 can be provided.

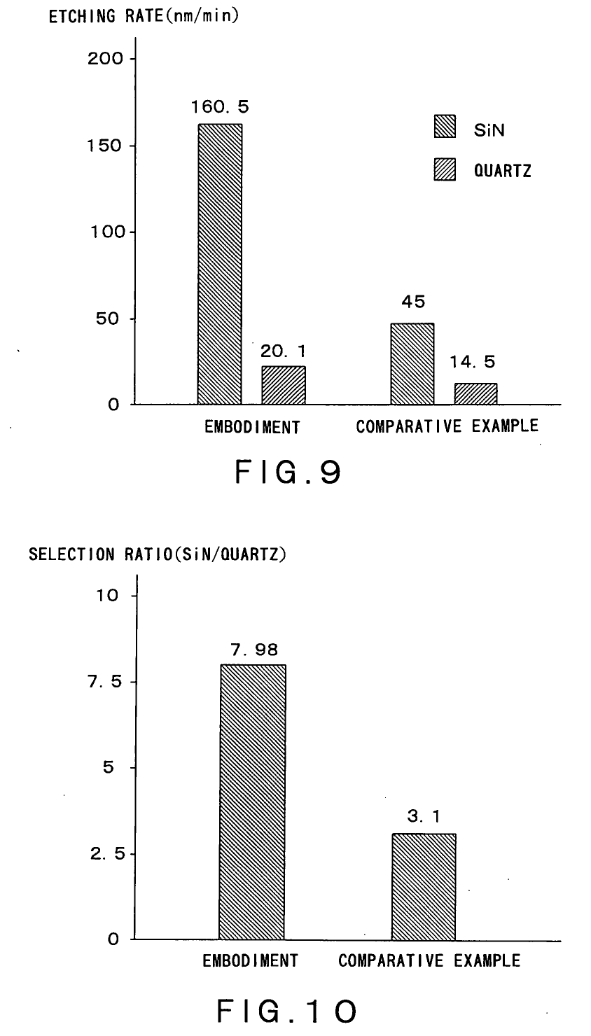

In order to confirm the effect of this invention, the etching rates and selection ratios, against the silicon nitride (SiN) and quarts, of the cleaning gas, under the conditions of the embodiment described above, were measured, respectively. Similarly, for comparison, the etching rates and selection ratios were also measured in the case (Comparative Example) where the mixed gas of hydrogen and nitrogen was supplied into the interior, by using the hydrogen introducing pipe 17d having a single-pipe structure. The results of the etching rates are shown in FIG. 9, and those of the selection ratios are shown in FIG. 10.

As shown in FIGS. 9 and 10, by supplying the hydrogen gas through the inner fluid passage 174 and the nitrogen gas through the outer fluid passage 175, by employing the hydrogen introducing pipe 17d having the double-pipe structure, the etching rate against the silicon nitride was improved four times or less and the selection ratio was enhanced 2.5 times or more, as compared with the conventional single-pipe structure. In such a manner, in this embodiment, the degradation of parts or components located in the vicinity of the nozzle of the hydrogen introducing pipe 17d can be suppressed while the etching rate and selection ratio can be enhanced.

As described above, according to this embodiment, by supplying the hydrogen gas fed through the inner fluid passage 174 into the reaction vessel 2 while the hydrogen gas is surrounded or wholly covered with the nitrogen gas fed through the outer fluid passage 175, degradation of the parts or components located in the vicinity of the nozzle of the hydrogen introducing pipe 17d can be suppressed. In addition, according to this embodiment, the etching rate and selection ratio can be enhanced.

It should be appreciated that the present invention is not limited to the above embodiment, but various modifications and applications may be provided. Hereinafter, another embodiment that can be applied to this invention will be discussed.

In the previous embodiment, while the case, in which the hydrogen introducing pipe 17d includes the inner pipe 171 and the outer pipe 172 configured to house the inner pipe 171 therein, has been described, the hydrogen introducing pipe 17d is not limited to such an aspect of the previous embodiment, but another hydrogen introducing pipe 17d that includes the inner fluid passage 174 and the outer fluid passage 175 configured to cover around the inner fluid passage 174 can also be applied to this invention.

In addition, while in the previous embodiment, the present invention has been adopted, with respect to the case in which the nitrogen gas is used as the protective gas, any other suitable gases that will not react with the fluorine and will not detrimentally affect the cleaning, such as helium (He), neon (Ne), argon (Ar) or xenon (Xe), can also be used as the protective gas.

Furthermore, while in the previous embodiment, the present invention has been described about the case in which the 20% fluorine gas diluted with nitrogen gas was employed as the fluorine gas, the fluorine gas may not be diluted with the nitrogen gas.

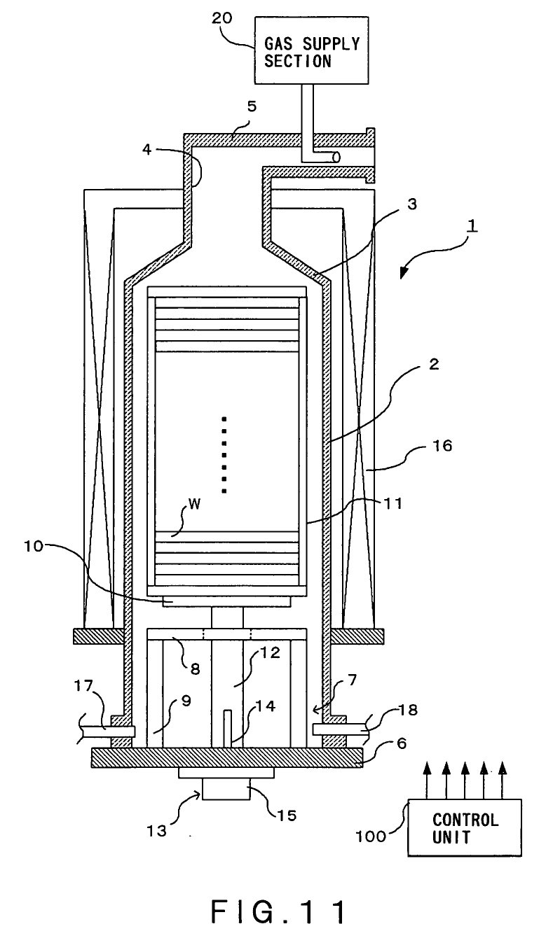

Additionally, while in the previous embodiment, the present invention has been described with respect to the case in which the gas supply section 20 is connected with the reaction vessel 2, the gas supply section 20 may be connected with, for example, the exhaust pipe 5 of the heating apparatus 1, as shown in FIG. 11. In this case, the gas supply section 20 is composed of a line for supplying the cleaning gas (fluorine gas and nitrogen gas).

As the film forming gas, any suitable gas can be selected, such that the deposits to be produced from the gas and attached to the inner walls and the like of the reaction vessel 2 due to the film forming process can be removed by the cleaning gas containing the fluorine gas and hydrogen gas, and such that it can be used for forming a thin film. For instance, it may be a mixed gas of hexachlorodisilane (HCD) and ammonia. The thin film to be formed on each object to be processed in the present invention is not limited to the silicon nitride.

While in the previous embodiment, the present invention has been described with respect to the case in which the batch-type heating apparatus having a single-pipe structure is used as the heating apparatus, this invention can also be applied to, for example, a batch-and-vertical-type heating apparatus having a double-pipe structure including the reaction vessel 2 composed of an inner pipe and an outer pipe. Alternatively, the present invention may be applied to a sheet-feeding-type heating apparatus.

The control unit 100 related to the embodiment of this invention is not limited to an exclusive system, but may be achieved by employing a computer system for use in common use. For instance, by installing programs for executing the aforementioned processes into a general-purpose computer from a storage medium (flexible disk, CD-ROM or the like), the control unit 100 for executing such processes can be provided.

The means for providing the aforementioned programs can be optionally selected. In addition to providing them via the storage medium as described above, they may be provided via, for example, a communication line, communication network, communication system or the like. In such a case, for example, the programs may be put up on a bulletin board system (BBS) of the communication network, and provided by superimposing the information on a carrier wave via the network. By activating the so-provided programs and executing them in a same manner as the other application programs under control of OS, the aforementioned processes can be performed.

1. A gas supply system for removing deposits attached to the interior of a film forming apparatus including a reaction chamber and an exhaust pipe connected with the reaction chamber, by supplying a cleaning gas, containing fluorine gas and hydrogen gas, into the reaction chamber of the thin film forming apparatus or into the exhaust pipe, the gas supply system comprising:
a fluorine supply means for supplying the fluorine gas into the reaction chamber or into the exhaust pipe; and
a hydrogen supply means for supplying the hydrogen gas into the reaction chamber or into the exhaust pipe, wherein
the hydrogen supply means includes an inner fluid passage and an outer fluid passage formed to cover around the inner fluid passage, and wherein the hydrogen gas is supplied through the inner fluid passage, while a protective gas, which will not react with the fluorine gas to be supplied from the fluorine supply means, is supplied through the outer fluid passage, whereby the hydrogen gas can be supplied into the reaction chamber or into the exhaust pipe, while it is covered with the protective gas.

2. The gas supply system according to claim 1, wherein the hydrogen supply means includes an inner pipe and an outer pipe formed to house the inner pipe therein, such that the inner fluid passage and outer fluid passage are formed of the inner pipe and outer pipe, respectively.

3. The gas supply system according to claim 1, wherein the hydrogen supply means is configured, such that the hydrogen gas is supplied, at 0.25 litters/min to 0.75 litters/min, through the inner fluid passage, and such that the nitrogen gas is supplied, at 1 litter/min to 5 litters/min, through the outer fluid passage.

4. The gas supply system according to claim 1, wherein the ratio of cross-sectional areas of the inner fluid passage and the outer fluid passage is within a range from 1:2 to 1:4.

5. The gas supply system according to claim 1, wherein the protective gas is nitrogen gas.

6. A thin film forming apparatus, comprising:
a reaction chamber into which an object to be processed is loaded and a film forming gas is then supplied, so as to form a thin film on the object to be processed;
an exhaust pipe connected with the reaction chamber; and
a gas supply system for supplying a cleaning gas containing fluorine gas and hydrogen gas into the reaction chamber or into the exhaust pipe, wherein
the gas supply system includes:
a fluorine supply means for supplying the fluorine gas into the reaction chamber or into the exhaust pipe;
a hydrogen supply means for supplying the hydrogen gas into the reaction chamber or into the exhaust pipe, wherein
the hydrogen supply means includes an inner fluid passage and an outer fluid passage formed to cover around the inner fluid passage, and wherein the hydrogen gas is supplied through the inner fluid passage, while a protective gas, which will not react with the fluorine gas to be supplied from the fluorine supply means, is supplied through the outer fluid passage, whereby the hydrogen gas can be supplied into the reaction chamber or into the exhaust pipe, while it is covered with the protective gas.

7. A gas supply method for removing deposits attached to the interior of a thin film forming apparatus including a reaction chamber and an exhaust pipe connected with the reaction chamber, by supplying a cleaning gas, containing fluorine gas and hydrogen gas, into the reaction chamber of the thin film forming apparatus or into the exhaust pipe, the gas supply method comprising the steps of:
supplying the fluorine gas into the reaction chamber or into the exhaust pipe from a fluorine supply means for supplying the fluorine gas; and
supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein
in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

8. The gas supply method according to claim 7, wherein in the step of supplying the hydrogen gas, the hydrogen gas is supplied, at 0.25 litters/min to 0.75 litters/min, through the inner fluid passage, and the nitrogen gas is supplied, at 1 litter/min to 5 litters/min, through the outer fluid passage.

9. The gas supply method according to claim 7, wherein the protective gas is nitrogen gas.

10. A method of cleaning a thin film forming apparatus including a reaction chamber and an exhaust pipe connected with the reaction chamber, for removing deposits attached to the interior of the thin film forming apparatus, the method comprising:
a gas supply method for supplying a cleaning gas, containing fluorine gas and hydrogen gas, into the reaction chamber of the thin film forming apparatus or into the exhaust pipe, in order to remove the deposits attached to the interior of the thin film forming apparatus, the gas supply method comprising the steps of:
supplying the fluorine gas into the reaction chamber or into the exhaust pipe from a fluorine supply means for supplying the fluorine gas; and
supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein
in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

11. A thin film forming method, comprising the steps of:
forming a thin film on each object to be processed by a thin film forming apparatus including a reaction chamber and an exhaust pipe connected with the reaction chamber, by supplying a film forming gas into a reaction chamber; and
cleaning, due to a gas supply method for supplying a cleaning gas containing fluorine gas and hydrogen gas, into the reaction chamber or into the exhaust pipe, in order to remove deposits attached to the interior of the thin film forming apparatus, the gas supply method comprising the steps of:
supplying the fluorine gas into the reaction chamber or into the exhaust pipe from a fluorine supply means for supplying the fluorine gas; and
supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein
in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

12. A storage medium for storing a computer program for driving a computer to perform a gas supply method for removing deposits attached to the interior of the thin film forming apparatus including the reaction chamber and the exhaust pipe connected with the reaction chamber, by supplying a cleaning gas containing fluorine gas and hydrogen gas, into a reaction chamber of a thin film forming apparatus or into an exhaust pipe, the gas supply method comprising the steps of:
supplying the fluorine gas into the reaction chamber or into the exhaust pipe from a fluorine supply section for supplying the fluorine gas; and
supplying the hydrogen gas into the reaction chamber or into the exhaust pipe from a hydrogen supply section including an inner fluid passage and an outer fluid passage formed to cover around the inner fluid passage, and adapted for supplying the hydrogen gas, wherein
in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.

13. A storage medium for storing a computer program for driving a computer to perform a method of cleaning a thin film forming apparatus including a reaction chamber and an exhaust pipe connected with the reaction chamber, for removing deposits attached to the interior of the thin film forming apparatus, the method of cleaning the thin film forming apparatus comprising:
a gas supply method for supplying a cleaning gas, containing fluorine gas and hydrogen gas, into the reaction chamber of the thin film forming apparatus or into the exhaust pipe, in order to remove the deposits attached to the interior of the thin film forming apparatus, the gas supply method comprising the steps of:
supplying the fluorine gas into the reaction chamber or into the exhaust pipe from a fluorine supply means for supplying the fluorine gas; and
supplying the hydrogen gas into the reaction chamber or into the exhaust pipe from a hydrogen supply means including an inner fluid passage and an outer fluid passage formed to cover around the inner fluid passage, and adapted for supplying the hydrogen gas, wherein
in the step of supplying the hydrogen gas, the hydrogen gas is supplied through the inner fluid passage, while a protective gas, which will not react with the fluorine gas to be supplied in the step of supplying the fluorine gas, is supplied through the outer fluid passage, whereby the hydrogen gas can be supplied into the reaction chamber or into the exhaust pipe, while it is covered with the protective gas.
